(19) United States
(12) Patent Application Publication
(10) Pub. No.: US 2005/0002241 A1
(43) Pub. Date: Jan. 6, 2005

(54) Memory system with improved signal integrity

(76) Inventors: Sung-Joo Park, Anyang-city (KR); Byung-Se So, Seongnam-city (KR); Jung-Joon Lee, Seoul (KR); Jae-Jun Lee, Yongin-city (KR); Chil-Nam Yoon, Suwon-city (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/837,610

(22) Filed: May 4, 2004

(30) Foreign Application Priority Data
May 6, 2003 (KR) 2003-28703

(51) Int. Cl. G11C 5/06

(52) U.S. Cl. 365/199

(57) ABSTRACT

A memory system includes a memory controller, a memory bus connected to the memory controller, and a plurality of memory modules connected along the memory bus, where each of the memory modules includes a plurality of memory devices. The system also includes a dummy stub or a dummy module connected to the memory bus between the memory controller and the memory module closest to the memory controller among the plurality of memory modules. The dummy stub or dummy module improves a signal integrity of at least the memory module closest to the memory controller.

### BACKGROUND OF THE INVENTION

1. Field of the Invention

The present invention generally relates to a memory system, and more particularly, the present invention relates to a memory system with improved signal integrity.

This U.S. non-provisional patent application claims priority under 35 U.S.C. § 119 of Korean Patent Application 2003-28703 filed on May 6, 2003, the entire contents of which are hereby incorporated by reference.

2. Description of the Related Art

A memory bus serves as a data transmission passage in a computer system. In conventional computer systems operating at low speed, the memory bus is provided to directly connect memory modules to a chip set, such as a memory controller. However, as the operating speed of computer systems has increased, conventional memory bus configurations have become a bottleneck in the system operation. Accordingly, new memory bus structures are being developed to accommodate for the increased operating speeds of computer systems.

While many types of memory systems are in existance, FIG. 1 schematically illustrates an example of a widely used memory system structure. Referring to FIG. 1, a main bus line MBL runs from a chip set MC to a termination voltage Vtt via a series resistor Rs, a plurality of memory modules MOD1, MOD2 and MOD3, and a termination resistor Rtt. Generally, memory modules are mounted on a memory system by being inserted into respective slots provided in respective sockets arranged on a main board at regular intervals.

As enumerated below, the memory bus structure shown in FIG. 1 suffers from certain drawbacks which derive from the memory modules MOD1, MOD2 and MOD3 being spaced at different distances from the memory controller MC.

First, the memory modules MOD1, MOD2 and MOD3 exhibit different signal integrities during read/write operations of the memory system. That is, the memory module MOD1 closest to the memory controller MC and the memory module MOD3 farthest from the memory controller MC have different signal transmission characteristics such as degree of attenuation and reflectivity of high frequency signals. In certain operating conditions, the data signal waveform of a given slot can be severely deformed. More particularly, in a memory system with a plurality of memory modules, the memory module closest to the memory controller has the worst signal integrity. The operating speed of a computer system is reduced by this worst-case operating condition.

Second, series resistors are used for obtaining an optimized operating condition in a conventional memory system, and hence the operating condition of the system depends on resistance values of the series resistors. However, there is a limit to which the operating conditions of the system can be changed since the size of the board is fixed and the number of resistors to be mounted on the board is limited.

### SUMMARY OF THE INVENTION

It is a feature of an embodiment of the present invention to provide a memory system with a memory bus structure capable of compensating for different distances of memory modules from a chip set such as memory controller, thereby improving signal integrity. In a memory system with at least two memory modules, the memory module exhibiting the worst signal integrity, i.e., the memory module closest to the chip set, is implemented as a dummy unit. The dummy unit may be implemented by a dummy stub which is an additional signal line provided on a main board of the memory system between the chip set and the memory module slot closest to the chip set. Alternatively, the dummy unit may be implemented by inserting a dummy memory module in the closest memory module slot.

The dummy stub includes channels with pads to which passive devices are attached having an impedance which is about the same as an impedance of normal memory modules. By using loads having impedance characteristics which are similar to those of a normal memory module, signal failures are compensated, and an operating condition of the memory system is optimized. That is, values of passive devices, lengths of the dummy stub, and locations of dummy slots may be changed to optimize an operating condition of the memory system.

To increase an operating speed of a memory system, an operating condition of the system is easily adjusted by changing the load of the dummy module or the location of the dummy slot in which the dummy module is inserted is changed. The memory system may be applied to computer systems operating at relatively high operating speeds or having relatively greater loads.

It is a feature of the present invention to provide a memory system with improved signal integrity.

It is another feature of the present invention to provide a memory system capable of increasing the number of loads to be run in conjunction with a memory controller without reducing an operating speed.

In accordance with one embodiment of the present invention, there is provided a memory system including a plurality of memory modules, each having a plurality of memory devices therein, a memory controller, a memory bus provided between the memory controller and the memory modules, and a dummy stub connected to the memory bus and located between the memory controller and the memory module closest to the memory controller among the memory modules.

In accordance with another embodiment of the present invention, there is provided a memory system including a plurality of memory modules, each having a plurality of memory devices therein, a memory controller, a memory bus provided between the memory controller and the memory modules, and a dummy module connected to the memory bus and located between the memory controller and the memory module closest to the memory controller among the memory modules.

### BRIEF DESCRIPTION OF THE DRAWINGS

The above and other features and advantages of the present invention will become readily apparent to those of ordinary skill in the art from the detailed description of preferred embodiments that follows, with reference to the accompanying drawings, in which:

FIG. 1 is a schematic diagram of a memory system in accordance with the conventional art;

FIG. 2 is a schematic diagram of a memory system in accordance with a first embodiment of the present invention;

FIG. 3 schematically illustrates the connection of a dummy stub in the memory system shown in FIG. 2;

FIG. 4 is a schematic diagram of a memory system in accordance with a second embodiment of the present invention;

FIG. 5 schematically illustrates a first example of signal connections between passive devices in a dummy module shown in FIG. 4;

FIG. 6 schematically illustrates a second example of signal connections between passive devices in a dummy module shown in FIG. 4;

FIG. 7A illustrates eye-shape data waveforms of a first memory module, which is the memory module closest to a chip set, during a write operation in the case where a dual-bank memory module is mounted on a memory system in accordance with the conventional art;

FIG. 7B illustrates eye-shape data waveforms of a first memory module, which is the closest memory module to a chip set, during a write operation in the case where a dual-bank memory module is mounted on the memory system in accordance with the present invention shown in FIG. 2;

FIG. 8A illustrates eye-shape data waveforms of a first memory module, which is the closest memory module to a chip set, during a read operation in the case where a dual-bank memory module is mounted on the memory system in accordance with the conventional art; and

FIG. 8B illustrates eye-shape data waveform of a first memory module, which is the closest memory module, during a read operation in the case where a dual-bank memory module is mounted on the memory system in accordance with the present invention shown in FIG. 2.

### DETAILED DESCRIPTION OF THE PREFERRED EMBODIMENTS

Hereinafter, preferred embodiments of the present invention will be described with reference to the accompanying drawings. Like reference numerals refer to like elements throughout the drawings.

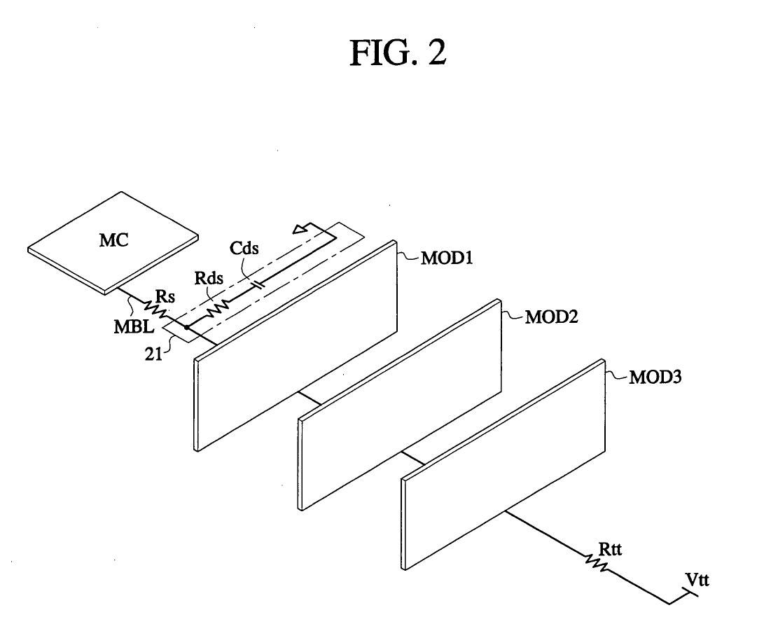

FIG. 2 schematically illustrates a memory system in accordance with a first embodiment of the present invention. Referring to FIG. 2, the memory system includes a plurality of memory modules MOD1, MOD2 and MOD3, each including a plurality of memory devices. The memory system further includes a memory controller MC, a memory bus MLB provided between the memory modules MOD1-MOD3 and the memory controller MC for data transmission, and a dummy stub 21 located between the memory controller MC and a memory module MOD1, and connected to the memory bus MBL. As shown, the memory module MOD1 is the closest to the memory controller MC among the memory modules MOD1-MOD3. A series resistor Rs is interposed between the memory controller MC and a connection point of the dummy stub 21 to the memory bus MLB. The memory bus MBL is connected between the memory controller MC and a termination voltage terminal Vtt, via the series resistor Rs, the dummy stub 21, the first memory module MOD1, the second module MOD2, the third memory module MOD3 and a termination resistor Rtt.

The operation of the memory system shown in FIG. 2 will be described below.

Data is received and transmitted between the memory controller MC and the memory modules MOD1, MOD2 and MOD3 through the memory bus MBL. As described above, in a conventional system the memory module located closest to the memory controller exhibits the worst signal integrity. In the present embodiment, however, the dummy stub 21 is instead located closest to the memory controller MC. Also, the dummy stub has electrical characteristics, such as impedance characteristics, which are similar to those of the memory modules MOD1, MOD2 and MOD3. Accordingly, the dummy stub 21 in effect exhibits the worst signal integrity instead of the first memory module MOD1, and signal integrity of the first memory module MOD1 is thus improved. In this embodiment, the dummy stub 21 includes a passive resistor Rds and a capacitor Cds. The optimized operating condition of the memory system is set by adjusting the resistance of the resistor Rds and the capacitance of the capacitor Cds. Alternately, or in addition, the optimized operation condition of the memory system may be set by changing a length of the dummy stub 21.

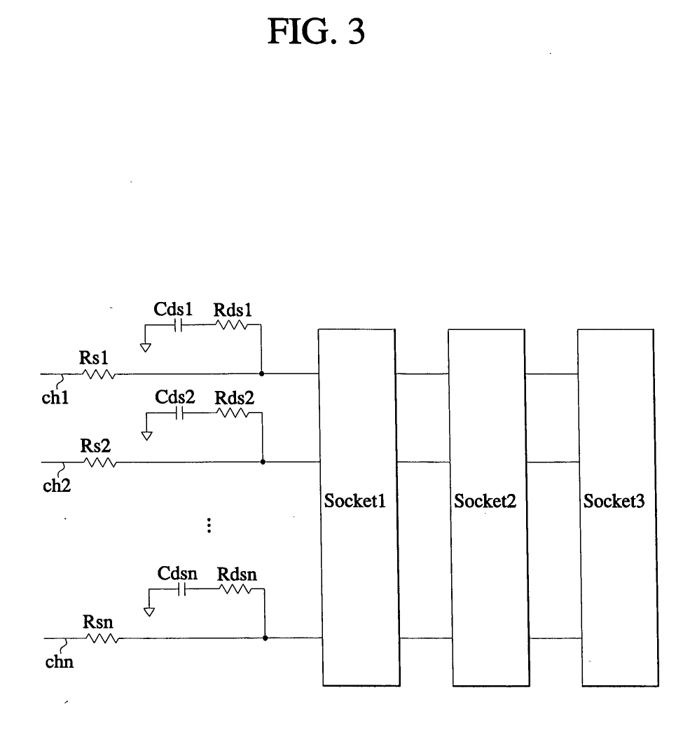

FIG. 3 illustrates the connection of the dummy stub 21 for each channel in the memory system shown in FIG. 2. The memory bus MBL in FIG. 2 includes a plurality (n) of channels (ch). The dummy stub 21 includes a plurality of unit dummy stubs corresponding to respective channels and all the unit dummy stubs are arranged between the memory controller Mc and the socket 1 of the first memory module MOD1 closest to the memory controller MC. As shown, each unit dummy stub includes a capacitor Cds and a resistor Rds connected in series between a reference voltage and a respective channel.

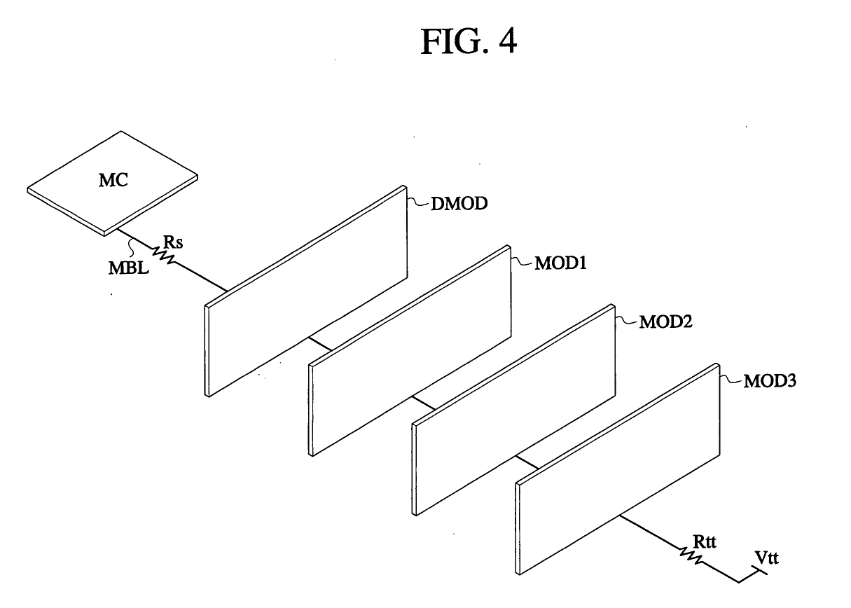

FIG. 4 schematically illustrates a memory system in accordance with an alternative embodiment of the present invention. Referring to FIG. 4, a memory system in accordance with the alternative embodiment of the present invention includes all the elements shown in FIG. 2, except for the dummy stub 21 of FIG. 2. Particularly, the memory system shown in FIG. 4 includes a dummy module DMOD in place of a dummy stub. Instead of memory devices, passive devices such as a resistor and a capacitor are contained in the dummy module DMOD. The optimized operating condition of the memory system is set by adjusting resistance and capacitance values of the resistor and the capacitor, respectively. Alternately, or in addition, the optimized operating condition of the memory system may be set by changing a distance between the passive devices connected to the dummy module DMOD and the memory bus MBL.

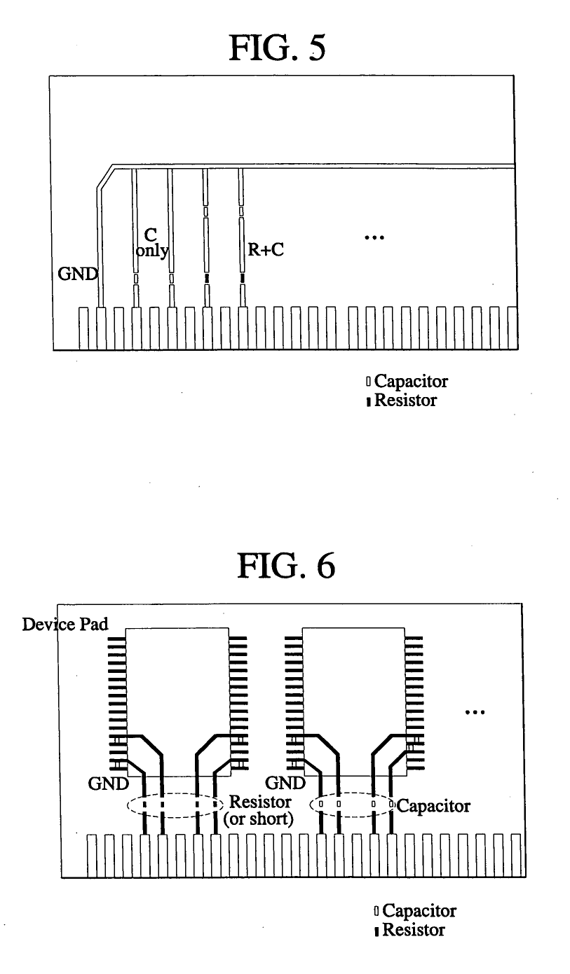

FIG. 5 illustrates a first example of the connection structure of passive devices in the dummy module. In the first example, the resistor R and the capacitor C form a load. By such a connection structure as shown in FIG. 5, adjusting of the load of dummy module is facilitated and the dummy module may be easily attached to and detached from the board of the memory system.

FIG. 6 illustrates a second example of a connection structure of passive devices in the dummy module. The dummy module is implemented using a memory module board. The memory module board has a plurality of pins to be connected to signal lines of a memory system board and pads to which pins of a memory device would be placed and connected. Capacitors and resistors are connected between data pads and ground pads. Further, the passive devices such as capacitors and resistors are connected to the pins of the memory module board. By changing the combination of the capacitors and resistors, or values of the passive devices, the optimized operating condition of the memory system can be obtained.

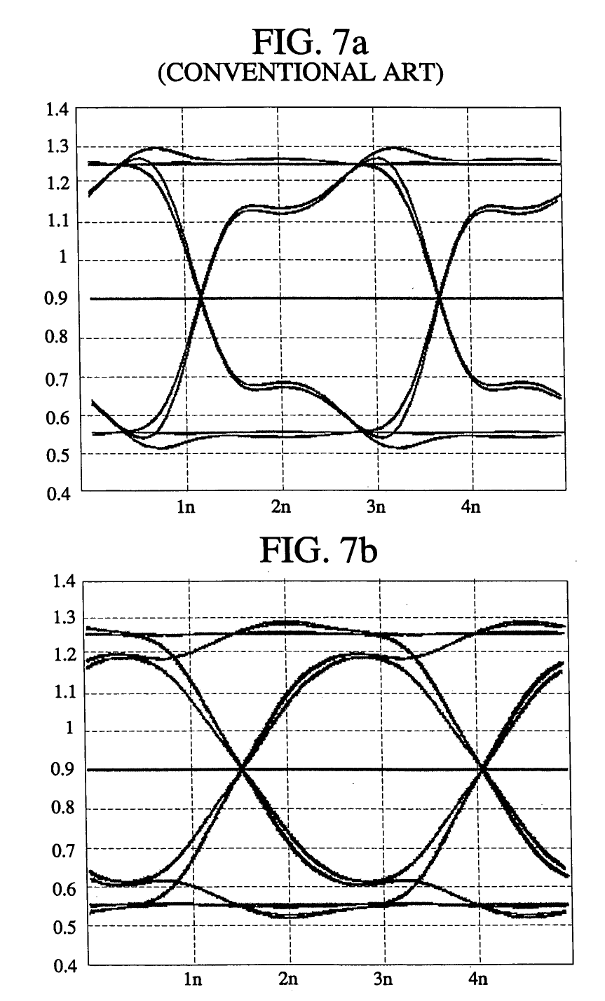

FIG. 7A illustrates eye-shape waveforms of data signals of a first memory module closest to a chip set during a write operation in the case where a dual-bank memory module is mounted on a memory system in accordance with the conventional art. FIG. 7B illustrates eye-shape waveforms of data signals of a first memory module closest to a chip set during the write operation in the case where a dual-bank memory module is mounted on a memory system in accordance with the embodiment of FIG. 2 of the present invention. As shown in FIG. 7A, the data signal is severely distorted in the case of conventional memory system but as shown in FIG. 7B, the data signal is minimally distorted in the case of prevent invention. That is, the memory module of the memory system of the present invention exhibits better signal integrity than that of conventional memory system.

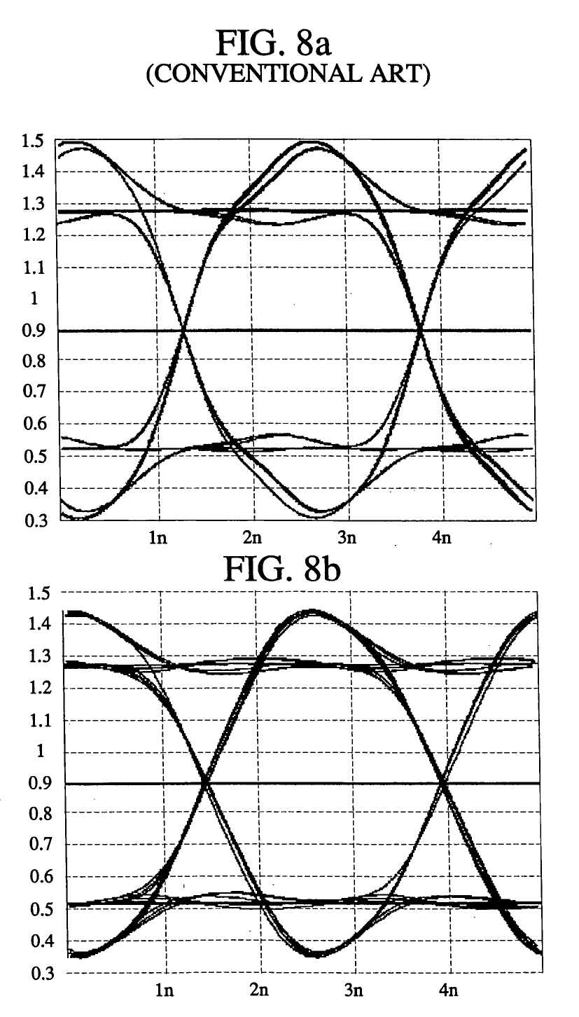

FIG. 8A illustrates eye-shape waveforms of data signals of a first memory module closest to a chip set during the read operation in the case where a dual-bank memory module is mounted on a memory system in accordance with the conventional art. FIG. 8B illustrates eye-shape waveforms of data signals of a first memory module closest to a chip set during the read operation in the case where a dual-bank memory module is mounted on a memory system in accordance with the embodiment of FIG. 2 of the present invention. As shown in FIGS. 8A and 8B, it is found that the degree of distortion of data signals of the memory system in accordance with the present invention is reduced in comparison with the degree of the distortion of the data signals of the conventional memory system. As shown in FIG. 8B, a ring back waveform moves from a position shown in FIG. 8A, and its size is reduced. Thus, the amplitude of the data is greater than that of FIG. 8A.

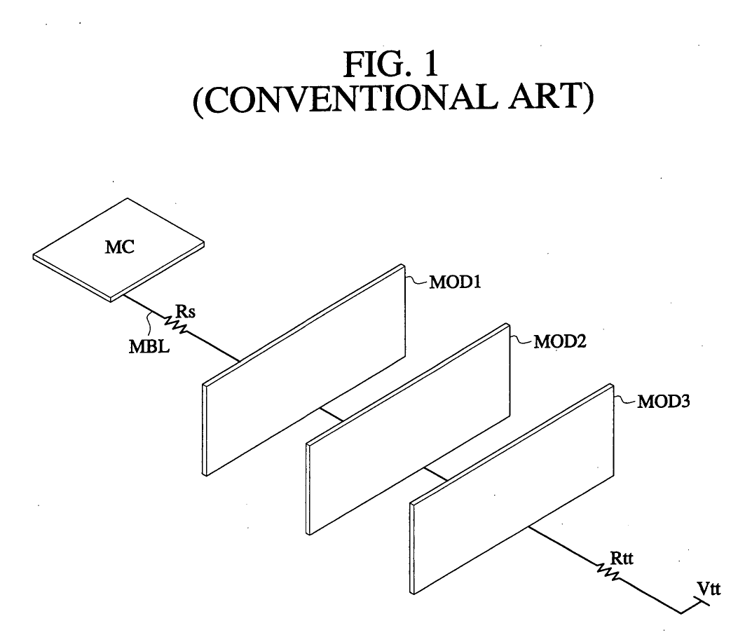

In the case of memory system of FIG. 1, 4 loads (4 modules×1 bank) are operable, but in the case of the memory system of FIG. 2, 6 loads (3 modules×2 banks) may be operable.

The above-discussed advantages associated with the embodiment of FIG. 2 are also realized in the embodiment of FIG. 4 of the application.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A memory system comprising:
a memory controller;
a memory bus connected to the memory controller;
a plurality of memory modules connected along the memory bus, each of the memory modules having a plurality of memory devices therein;
a dummy stub connected to the memory bus between the memory controller and the memory module closest to the memory controller among the plurality of memory modules.

2. The memory system according to claim 1, wherein dummy stub improves a signal integrity of at least the memory module closest to the memory controller.

3. The memory system according to claim 1, wherein an impedance of the dummy stub is substantially the same as an impedance of each of the memory modules.

4. The memory system according to claim 1, wherein the dummy stub comprises passive devices connected to the memory bus.

5. The memory system according to claim 4, wherein an optimized operating speed of the memory system is obtained by changing values of the passive devices.

6. The memory system according to claim 1, wherein an optimized operating speed of the memory system is obtained by changing a length of the dummy stub.

7. A memory system comprising:
a memory controller;
a memory bus connected to the memory controller;
a plurality of memory modules connected along the memory bus, each of the memory modules having a plurality of memory devices therein;
a dummy module connected to the memory bus between the memory controller and the memory module closest to the memory controller among the plurality of memory modules.

8. The memory system according to claim 7, wherein the dummy module improves a signal integrity of at least the memory module closest to the memory controller.

9. The memory system according to claim 7, wherein an impedance of the dummy module is substantially the same as an impedance of each of the memory modules.

10. The memory system according to claim 7, wherein the dummy module comprises a memory module board and passive devices attached on the memory module board and connected to the memory bus.

11. The memory system according to claim 10, wherein an optimized operating speed of the memory system is obtained by changing values of the passive devices attached on the memory module board.

12. The memory system according to claim 10, wherein an optimized operating speed of the memory system is obtained by changing lengths of signal lines from the passive devices attached onto memory module board to the memory bus.
